(19) United States
(12) Patent Application Publication
(10) Pub. No.: US 2021/0104376 A1
(43) Pub. Date: Apr. 8, 2021

(54) DEVICE FOR PROVIDING ELECTRONS AND METHOD FOR MAKING THE SAME

(71) Applicant: City University of Hong Kong, Kowloon (HK)

(72) Inventors: Fu-Rong Chen, Kowloon (HK); Kai-Wen Wu, Taoyuan City (HK); Ying-Shuo Tseng, Hsinchu City (TW); Pei-En Li, Hsinchu City (TW); Yu-Chun Hsueh, Kowloon (HK)

(21) Appl. No.: 16/592,875

(22) Filed: Oct. 4, 2019

(51) Int. Cl. H01J 37/285; H01J 37/075; H01J 37/26

(52) U.S. Cl. CPC H01J 37/285; H01J 37/261; H01J 37/075

(57) ABSTRACT

A device for providing electrons and its method of making. The device includes an optical fiber with a tip and a metallic arrangement arranged at the tip. The metallic arrangement is arranged to be excited by an energy source to emit electrons or electron beams.

### TECHNICAL FIELD

The invention relates to a device for providing electrons and its method of making.

### BACKGROUND

Electron microscopes generally include a device for providing electrons. The device for providing electrons may be a thermionic tungsten filament that is resistively heated to release electrons, or may be a solid tungsten tip that is irradiated with an energy source (e.g., laser source) to provide electron beams. The electron or electron beams provided by the latter is generally more coherent and brighter. Problematically, however, accurately irradiating the tungsten tip, especially when the tip size is small, can be quite challenging.

### SUMMARY OF THE INVENTION

In accordance with a first aspect of the invention, there is provided a device for providing electrons, comprising: an optical fiber with a tip and a metallic arrangement arranged at the tip. The metallic arrangement is arranged to be excited by an energy source to emit electrons or electron beams. The tip is preferably sized in micro-scale, more preferably in nano-scale. The tip may include a sharp end or a rounded end. The rounded end may have a radius of less than 100 nm.

In one embodiment of the first aspect, the metallic arrangement comprises a metallic surface at the tip. The metallic arrangement may be made from chromium (Cr), gold (Au), or tungsten (W).

In one embodiment of the first aspect, the metallic arrangement comprises a metallic coating at the tip. In one embodiment of the first aspect, the metallic arrangement comprises a plurality of layers of metallic coating at the tip. The plurality of layers of metallic coating can be of the same metallic material or of different metallic materials.

In one embodiment of the first aspect, the energy source is a pulsed laser source arranged to provide laser pulses to excite the metallic arrangement to emit pulses of electrons or pulses of electron beams. Preferably, the laser pulses are femtosecond laser pulses. The device may be incorporated in an electron microscope, preferably a transmission electron microscope (e.g., femtosecond transmission electron microscope), for providing a field emission source that provides electrons or electron beams for microscopy.

In accordance with a second aspect of the invention, there is provided an electron source comprising: a device for providing electrons and an energy source. The device includes an optical fiber with a tip and a metallic arrangement arranged at the tip and arranged to be excited by an energy source to emit electrons or electron beams. The energy source is arranged to provide energy to the device to cause emission of electrons from the metallic arrangement. The electron source may be a field emission source. The tip is preferably sized in micro-scale, more preferably in nano-scale. The tip may include a rounded end. The rounded end may have a radius of less than 100 nm.

In one embodiment of the second aspect, the metallic arrangement comprises a metallic surface at the tip. The metallic arrangement may be made from chromium (Cr), gold (Au), or tungsten (W).

In one embodiment of the second aspect, the metallic arrangement comprises a metallic coating at the tip. In one embodiment of the first aspect, the metallic arrangement comprises a plurality of layers of metallic coating at the tip. The plurality of layers of metallic coating can be of the same metallic material or of different metallic materials.

In one embodiment of the second aspect, the energy source includes a pulsed energy source arranged to provide energy pulses to excite the metallic arrangement to emit pulses of electrons or pulses of electron beams. In one example, the pulsed energy source includes a pulsed laser source arranged to provide laser pulses to excite the metallic arrangement to emit pulses of electrons or pulses of electron beams. Preferably, the laser pulses are femtosecond laser pulses. As such the electron source may be a pulsed electronic source that can provide femtosecond time resolution.

In accordance with a third aspect of the invention, there is provided an electron microscope including the device of the first aspect. The electron microscope may be a transmission electron microscope (e.g., femtosecond transmission electron microscope).

In accordance with a fourth aspect of the invention, there is provided an electron microscope including the electron source of the second aspect. The electron source may be a field emission source. The electron microscope may be a transmission electron microscope (e.g., femtosecond transmission electron microscope).

In accordance with a fifth aspect of the invention, there is provided a method for producing a device for providing electrons. The method includes forming an optical fiber with a tip and arranging a metallic arrangement at the tip. The metallic arrangement is arranged to be excited by an energy source to emit electrons or electron beams. The device for providing electrons may be the device of the first aspect.

In one embodiment of the fifth aspect, forming an optical fiber with a tip comprises melting a portion of the optical fiber to form the tip. The melting of the portion of the optical fiber may be performed using laser. In one embodiment of the fifth aspect, forming an optical fiber with a tip further comprises tensioning the optical fiber during the melting of the portion of the optical fiber. In some embodiments the tension applied may be constant; in some other embodiments the tension applied may be adjustable (increasing or decreasing).

In one embodiment of the fifth aspect, arranging a metallic arrangement at the tip comprises coating a metallic layer on the tip. The coating may be performed using electron beam evaporation or pulsed laser deposition. In one embodiment of the fifth aspect, arranging a metallic arrangement at the tip comprises coating a plurality of metallic layers on the tip. The plurality of metallic layers can be of the same metallic material or of different metallic materials.

### BRIEF DESCRIPTION OF THE DRAWINGS

Embodiments of the invention will now be described, by way of example, with reference to the accompanying drawings in which:

FIG. 1A is a schematic diagram of a device for providing electrons in one embodiment of the invention; Figure B is a sectional view of the device of FIG. 1A taken along the line X-X;

FIG. 2 is a flow chart of a method for producing a device for providing electrons in one embodiment of the invention;

FIG. 3 is a schematic diagram of a system for producing the device of FIG. 1 in one embodiment of the invention;

FIG. 4 is a graph showing a relationship of the material energy barrier (eV) and distance of electronics from the metallic surface (nm) of the device of FIG. 1 for different materials (M1, M2, M3); and

FIG. 5 is a schematic diagram of a transmission electron microscope incorporating the device of FIG. 1.

### DETAILED DESCRIPTION OF THE PREFERRED EMBODIMENT

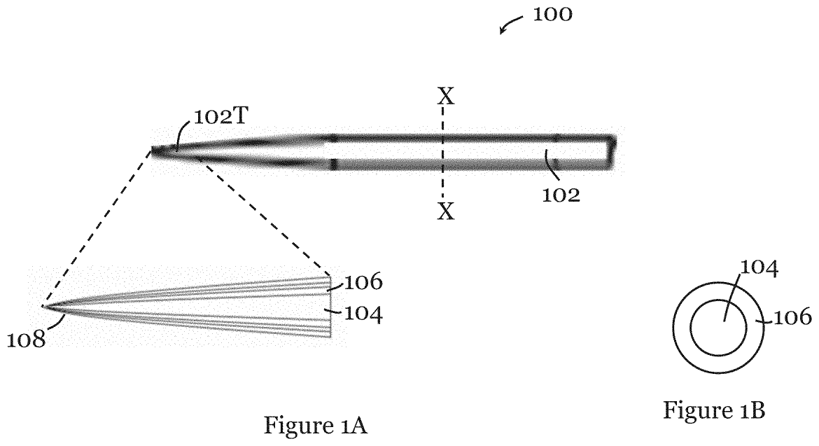

FIGS. 1A and B show an optical fiber 100 operable as a device for providing electrons in one embodiment of the invention. The optical fiber 100 includes an elongated body 102 with a tip 102T. In this embodiment, the tip 102T is a nano-tip sized in nano-scale. The optical fiber 100 has a core 104 and a cladding 106 arranged around the core 104, as shown in FIG. 1B. A metallic arrangement, in the form of metallic layers 108 made with a material that has a low work function, is arranged at the tip 102T. The optical fiber 100 has an open end at which the metallic arrangement is arranged to allow the metallic arrangement to be excited by an energy source. The metallic arrangement can be made from chromium (Cr), gold (Au), or tungsten (W). The metallic layers 108 are arranged to be excited by an energy source (not shown) to emit electrons or electron beams from its surface. The energy source may be a pulsed laser source that transmits laser pulses through the optical fiber 100 (e.g., at the other end away from the tip 102T) to generate pulses of electron beams at the end of the tip 102T.

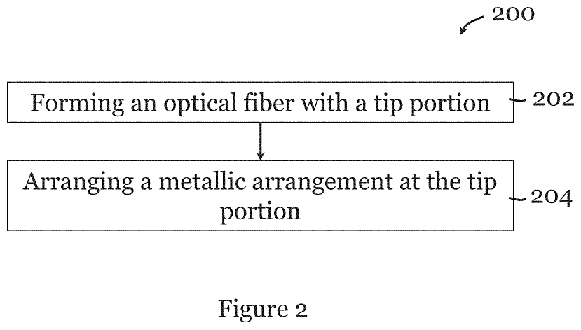

A method 200 for producing a device for providing electrons in one embodiment of the invention is shown in FIG. 2. The device may be the device 100 in FIGS. 1A and 1B. The method 200 includes, first, in step 202, forming an optical fiber with a tip and then, in step 204, arranging a metallic arrangement at the tip. In step 202, forming the optical fiber with a tip may include melting a portion of the optical fiber to form the tip, e.g., using laser. The optical fiber may be tensioned during the melting. The tension applied may be generally increased as the portion melts. In step 204, arranging a metallic arrangement at the tip may include applying one or more metallic coatings to the tip. The coating may be performed using electron beam evaporation or pulsed laser deposition.

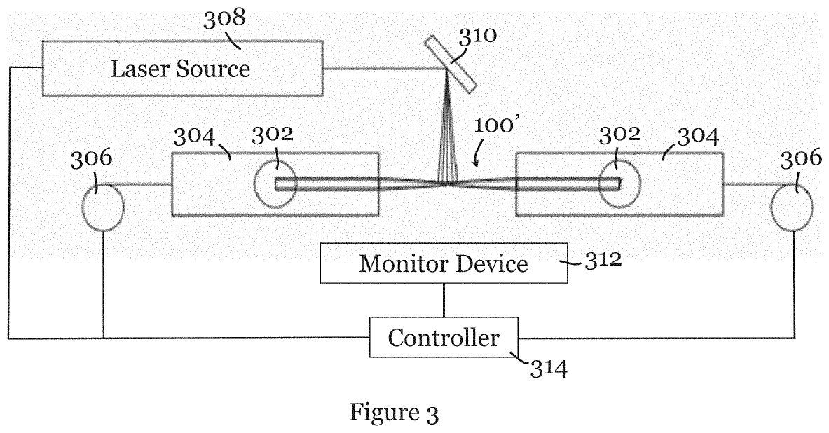

FIG. 3 shows a system 300 for producing a device 100 for providing electrons in one embodiment of the invention. The system 300 is used to create an optical fiber 100′ with a tip, e.g., like the one in FIG. 1. The tip created may be in nano-scale. In one example, the tip may have a tip radius of smaller than 100 nm. The system 300 includes a pair of clamps 302 for clamping an optical fiber (to be processed to produce a tip). The clamps 302 are mounted on respective movable platforms 304 that can be selectively moved towards and away from each other to adjust a tensioning of the clamped optical fiber 100′. The platforms 302 are each connected with a respective driving source (e.g., motor) 306 to affect its movement. The system includes an energy source, e.g., laser source 308 (with a CO₂ laser cavity) arranged to provide laser energy for melting a portion of the optical fiber to form a tip, and an optical mirror 310 for directing the laser to the optical fiber. The system 30o also includes a monitor device 312, e.g., a camera, for monitoring the processing status of the optical fiber, e.g., the shape of the optical tip during processing. A controller 314 is operably connected with the monitor device 312, the driving sources 306 and the laser source 308, to control the processing of the optical fiber 100′. The controller 314 may include a processor and a memory. The processor may be formed by one or more CPU, MCU, controllers, logic circuits, Raspberry Pi chip, etc. The controller 314 is arranged to receive data indicative of the status (shape, form, etc.) of the tip of the fiber 100′ from the monitor device 312, process the received data to determine the status of the tip, and then provide output to control operation of the driving sources 306 and the laser source 308. For example, the controller may control the power of the laser source, the movement of the clamps 304 (which affect tension of the optical fiber 100′) based on the status of the tip detected by the monitor device 312. The controller 314 provides a feedback system that allows the fiber tip's radius and surface topography to be accurately controlled.

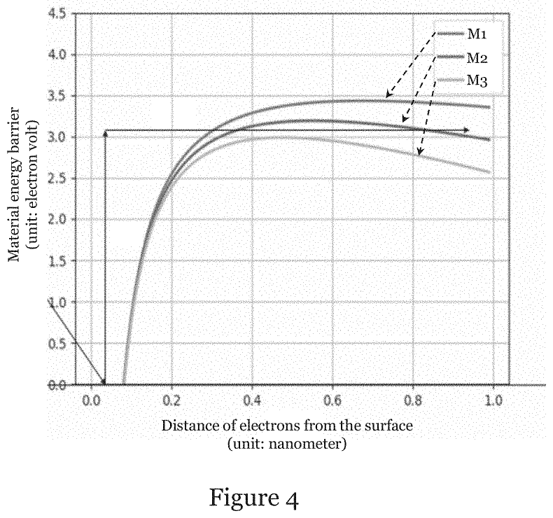

FIG. 4 illustrates excitation of electrons in a metallic arrangement of a device for providing electrons, such as the device 100 in FIG. 1. In FIG. 4, the x-axis represents the distance of electrons from the surface of the metallic arrangement (at the tip of the device) and the y-axis represents the material energy barrier. Note that the device may already have been placed in an appropriate electric field that reduces the barrier. The graph in FIG. 4 shows three lines, each representing a different material M1, M2, M3 for the metallic arrangement. The material energy barrier with 0 eV represents the Fermi level. When femtosecond laser pulses are provided to the device hence the metallic arrangement, the laser excites the electrons to a high- (or higher-) energy level, sufficient for the electrons to overcome the energy barrier escape from the metallic arrangement.

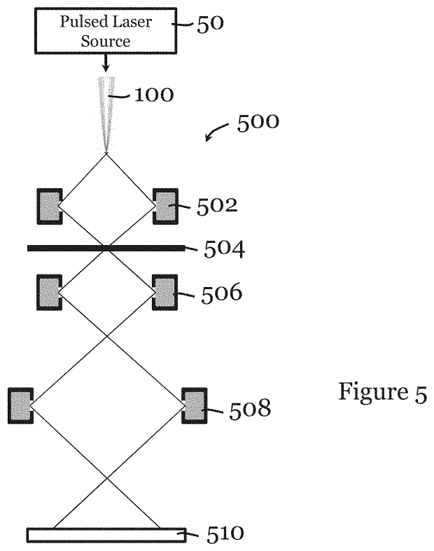

FIG. 5 shows a transmission electron microscope 500 incorporating the device 100 of FIG. 1. The transmission electron microscope 500 is the same as existing ones (having, among others, condenser lens 502, specimen 504, objective lens 506, projection lens 508, and image plane 510), except that the electron source includes the device 100 of FIG. 1 (only tip shown, for simplicity) and a pulsed laser source 50 operably connected to the device 100. The device 100 may be placed in an electric field that assist generation of electrons or electron beams from the tip. The electron source with the pulsed laser source 5o and the device 100 may be arranged, like the other components of the microscope 500, in a vacuum environment. In this embodiment, the laser source injects laser beams or pulses into ultra-high vacuum through ultra-high vacuum (e.g., 10⁻¹⁰ torr) fiber feedthrough and then transmitted from one end of the fiber to the tip of the fiber 100. The laser beams or pulses arriving at the tip excite the electrons, allowing the electrons to be excited to leave the metallic layers, in the form of electron beam pulses. In one application, when femtosecond pulsed laser is used to excite the electrons at the metallic arrangement, an ultrafast pulse electron source can be produced. In general, there are two ways to increase electron or electron beam emission: (1) use pulsed laser with shorter wavelength as they can excite electrons to a higher energy level; and (2) use material with low work function to reduce the energy barrier. The energy source in this example essentially acts as a field emission electron gun, a high brightness electron source with high spatial and temporal resolution. The laser beams or pulses can be controlled to reduce the space charge effect and to increase the spatial resolution.

Some of the above embodiments have provided a pulsed electron source for electron microscopes. The electron source can add femtosecond analysis capability to electron microscopes. By using pulsed laser and optical fiber tip, a highly coherent pulsed electron source can be achieved while avoiding alignment difficulties (associated with aligning the energy source and the tip). The electron source can provide not only high spatial resolution but also femtosecond time resolution. In some embodiments, the electron source can be incorporated into a transmission electron microscope to boost temporal resolution to add femtosecond analysis capability (some molecular processes occur at a time scale of femtoseconds (10⁻¹⁵ seconds)).

It will also be appreciated that where the methods and systems of the invention are either wholly implemented by computing system or partly implemented by computing systems then any appropriate computing system architecture may be utilized. This will include stand-alone computers, network computers, dedicated or non-dedicated hardware devices. Where the terms “computing system” and “computing device” are used, these terms are intended to include any appropriate arrangement of computer or information processing hardware capable of implementing the function described.

It will be appreciated by persons skilled in the art that numerous variations and/or modifications may be made to the invention as shown in the specific embodiments without departing from the spirit or scope of the invention as broadly described. The described embodiments of the invention should therefore be considered in all respects as illustrative, not restrictive.

For example, the device for providing electrons can be of different sizes, e.g., in micro- or nano-scale. The optical fiber can take different shape, form, or dimension, provided that it includes a tip where a metallic arrangement is arranged. The metallic arrangement of the device for providing electrons need not be in the form of layer(s). In embodiments in which the metallic arrangement includes layers, the number of layers may vary and the material of different layers can be different. The energy source for exciting the metallic arrangement of the device can take any suitable form, including but not limited to a laser source. Depending on the energy source, the metallic arrangement may be excited to provide electrons or electron beams. The device can be made using different methods as generally encompassed by the method illustrated in FIG. 2. The device can be but not necessarily be made using the system of FIG. 3. The system in FIG. 3 can include a different energy source in place of laser. The clamps need not both be movable, but instead can be movable with respect to each other (one fixed, one movable). The optical fiber can be clamped at only one clamp such that the optical fiber has a free end to be processed to form a tip.

1. A device for providing electrons, comprising:
an optical fiber with a tip; and
a metallic arrangement arranged at the tip and arranged to be excited by an energy source to emit electrons or electron beams.

2. The device of claim 1, wherein the tip is sized in micro- or nano-scale.

3. The device of claim 1, wherein the metallic arrangement comprises a metallic surface at the tip.

4. The device of claim 3, wherein the metallic arrangement is made from chromium, gold, or tungsten.

5. The device of claim 1, wherein the metallic arrangement comprises a metallic coating at the tip.

6. The device of claim 1, wherein the energy source is a pulsed laser source arranged to provide laser pulses to excite the metallic arrangement to emit pulses of electrons or pulses of electron beams.

7. The device of claim 6, wherein the laser pulses are femtosecond laser pulses.

8. An electron source, comprising:
a device for providing electrons, including
an optical fiber with a tip; and
a metallic arrangement arranged at the tip and arranged to be excited by an energy source to emit electrons or electron beams; and
an energy source arranged to provide energy to the device to cause emission of electrons from the metallic arrangement.

9. The electron source of claim 8, wherein the tip is sized in micro- or nano-scale.

10. The electron source of claim 8, wherein the metallic arrangement comprises a metallic surface at the tip.

11. The electron source of claim 10, wherein the metallic arrangement is made from chromium, gold, or tungsten.

12. The electron source of claim 8, wherein the metallic arrangement comprises a metallic coating at the tip.
The electron source of claim 8, wherein the metallic arrangement comprises a plurality of layers of metallic coating at the tip.

13. The electron source of claim 8, wherein the energy source includes a pulsed energy source arranged to provide energy pulses to excite the metallic arrangement to emit pulses of electrons or pulses of electron beams.

14. The electron source of claim 13, wherein the pulsed energy source includes a pulsed laser source arranged to provide laser pulses to excite the metallic arrangement to emit pulses of electrons or pulses of electron beams.

15. The electron source of claim 9, wherein the laser pulses are femtosecond laser pulses.

16. An electron microscope comprising the device of claim 1.

17. The electron microscope of claim 16, wherein the electron microscope is a transmission electron microscope.

18. A method for producing a device for providing electrons, comprising:
forming an optical fiber with a tip; and
arranging a metallic arrangement at the tip,
wherein the metallic arrangement being arranged to be excited by an energy source to emit electrons or electron beams.

19. The method of claim 18, wherein forming an optical fiber with a tip comprises:
melting a portion of the optical fiber to form the tip.

20. The method of claim 19, wherein the melting of the portion of the optical fiber is performed using laser.

21. The method of claim 19, wherein forming an optical fiber with a tip further comprises:
tensioning the optical fiber during the melting of the portion of the optical fiber.

22. The method of claim 21, wherein the tension applied is constant.

23. The method of claim 21, wherein the tension applied is generally increasing.

24. The method of claim 18, wherein arranging a metallic arrangement at the tip comprises coating a metallic layer on the tip.
